(19) United States
(12) Patent Application Publication
(10) Pub. No.: US 2009/0166856 A1
(43) Pub. Date: Jul. 2, 2009

(54) Semiconductor Device

(76) Inventor: Yuki Iwata, Kyoto (JP)

Correspondence Address: CANTOR COLBURN, LLP, 20 Church Street, 22nd Floor, Hartford, CT, 06103, US

(21) Appl. No.: 11/792,261

(22) PCT Filed: Nov. 25, 2005
(86) PCT No.: PCT/JP05/21686

§ 371 Date: Mar. 20, 2008

(30) Foreign Application Priority Data
Dec. 3, 2004 (JP) 2004-350882

(51) Int. Cl. H01L 23/482; H01L 23/12

(52) U.S. Cl. 257/737; 257/E23.012; 257/E23.068

(57) ABSTRACT

A semiconductor device is provided whereby the signal interference among a plurality of function blocks is reduced.

In a semiconductor device having a CSP structure, an integrated circuit containing a plurality of function blocks is formed on a semiconductor substrate. A plurality of external electrodes are classified into a plurality of groups of external electrodes according to function blocks connected, and are arranged in a plurality of divided regions for each of the plurality of groups of external electrodes. Rewirings connected to external electrodes of low impedance are placed in a boundary area between the plurality of regions.

### TECHNICAL FIELD

This invention relates to semiconductor devices, and it particularly relates to a semiconductor device utilizing rewiring.

### BACKGROUND TECHNOLOGY

As information terminals, such as mobile phones and PDAs (Personal Digital Assistance), grow smaller in size in recent years, there is a growing demand for smaller sizes of LSIs and other semiconductor devices used in them. In these circumstances, attention is being focused on a packaging technology called BGA (Ball Grid Array) structure.

Unlike the conventional QFP (Quad Flat Package) structure in which they are connected to a substrate via a lead frame, the BGA structure is such that the semiconductor devices are connected to the substrate via terminals provided on the surfaces of semiconductor devices, which are called solder bumps or solder balls. This BGA structure allows the provision of terminals for external connection all over the surfaces of semiconductor devices and can reduce the packaging area greatly because there is no need for lead frames around the components.

Using the BGA structure like this, a packaging technology, called CSP (Chip Size Package) technology, has been developed, in which the area of a semiconductor chip and the packaging area are about the same. Furthermore, a technology called WL-CSP (Wafer Level CSP) has been developed, in which solder bumps are formed directly on a semiconductor chip without the medium of a substrate, thus making semiconductor devices even smaller in size (Patent Document 1).

As shown in FIG. 1 of Patent Document 1, a semiconductor device to which CSP technology like this is applied is often connected to a printed-circuit board, with the external connection terminals formed by solder bumps arranged regularly on the surface of the semiconductor device.

On the other hand, a semiconductor integrated circuit is formed on a semiconductor substrate, and electrode pads for input and output of signals are often arranged along the periphery of the semiconductor integrated circuit in the same way as with the QFP structure. These electrode pads formed along the periphery of the semiconductor integrated circuit are led around to the positions of the regularly-arranged solder bumps by a rewiring layer to be connected electrically.

[Patent Document 1]

Japanese Patent Application Laid-Open No. 2003-297961.

A semiconductor device to which CSP technology is applied allows a reduction in packaging area but ends up with closer distances between terminals. Especially with the WL-CSP technology, signals are led around by rewiring from the electrodes on the semiconductor chip surface to the positions of the bumps and connected to the bumps by the electrode portion called the post, so that the presence of parasitic capacitance between the electrodes can no longer be ignored and there will be problems of cross talk between the electrode terminals and sneaking-in of noise.

### DISCLOSURE OF THE INVENTION

The present invention has been made in view of these problems and an object thereof is to provide a semiconductor device with reduced signal interference between a plurality of function blocks.

In order to solve the above problems, a semiconductor device according to an embodiment of the present invention comprises: a semiconductor substrate on which an integrated circuit including a plurality of function blocks is formed; and a plurality of external electrodes which are formed as connection terminals to an external circuitry wherein the plurality of external electrodes are connected, via rewiring, to a plurality of electrode pads provided on the integrated circuit. The plurality of external electrodes are classified into a plurality of groups of external electrodes according to function blocks connected thereto and are arranged in a plurality of divided regions for each of the plurality of groups of external electrodes. Rewiring connected to an external electrode of low impedance is placed in a boundary area between the plurality of regions.

“A plurality of electrode pads provided on the integrated circuit” denotes the electrode pads provided for supplying signals to the circuit elements that constitute the integrated circuit, for pulling out the signals or for the grounding or the like. The “external electrodes” are meant to be the electrodes that function as connection terminals, such as solder balls, solder bumps and posts, with an external circuit.

According to this embodiment, in an integrated circuit, a plurality of function blocks, where the signal interference is not desired, are formed by dividing them into a plurality of regions. And the external electrodes connected respectively to the function blocks are arranged by dividing them into a plurality of regions and thereby the external electrodes are cut off electrically from one another by the rewiring of the low impedance. Hence, the signal interference among a plurality of regions separated by the rewirings can be reduced.

At least one function block among the plurality of function blocks may be a small-signal circuit for treating small signals.

Another function block among the plurality of function blocks may be a large-signal circuit for treating large signals.

The small-signal circuit for treating small signals may be, for example, a circuit for processing digital signals or an analog control circuit, whereas the large-signal circuit for treating large signals includes a power transistor and the like and may be a circuit for treating the large current or high voltage and so forth. However, the small-signal circuit and the large-signal circuit may be distinguished from each other, based on a relative relation in signal level.

The rewiring connected to an external electrode of low impedance may be a ground line connected to an external ground terminal or a power supply line connected to a supply voltage terminal.

When the rewiring, placed in a boundary area of a plurality of regions, which is connected to the external electrodes of low impedance serves as a ground line, the signals will be released to the external ground terminals, so that the signal interference among a plurality of regions can be reduced. When this rewiring serves as a power supply line, the signals can be released via a bypass capacitor connected externally or the like, so that the signal interference among a plurality of regions can be reduced.

It is desirable that this rewiring be formed thickly within a range permissible by a process rule.

The rewiring connected to an external electrode of low impedance may be provided in plurality and a plurality of rewirings may be placed mutually adjacent. Thereby, the signal interference can be reduced more suitably.

Two of the plurality of rewirings connected to external electrodes of low impedance may be any of one of combinations among (i) ground line and power supply line, (ii) ground line and ground line and (iii) power supply line and power supply line.

The rewirings connected to external electrodes of low impedance may be such that three lines are placed adjacent in the order of a ground line, a power supply line and a ground line.

The rewiring connected to an external electrode of low impedance may be connected with the external electrodes of low impedance at both ends thereof.

Power supply terminals, ground terminals or the like are connected to the both ends of rewiring that serves as shield wiring. This can lower the impedance of the rewiring and stabilize the potential, and thereby the signal interference among a plurality of regions can be reduced more suitably.

It is to be noted that arbitrary combinations of the above-described components and expression of the present invention changed among a method, an apparatus, a system and so forth are also effective as the present embodiments.

### BRIEF DESCRIPTION OF THE DRAWINGS

FIG. 1 is a diagram showing a semiconductor device according to an embodiment of the present invention as viewed from an electrode-pad side.

FIG. 2 is a sectional view taken on line 2-2 of FIG. 1.

FIG. 3 is a diagram showing an arrangement of a semiconductor integrated circuit formed on a semiconductor substrate.

FIG. 4 is a diagram showing a modification of a semiconductor device according to an embodiment.

FIG. 5 is a diagram showing another modification of a semiconductor device according to an embodiment.

### THE BEST MODE FOR CARRYING OUT THE INVENTION

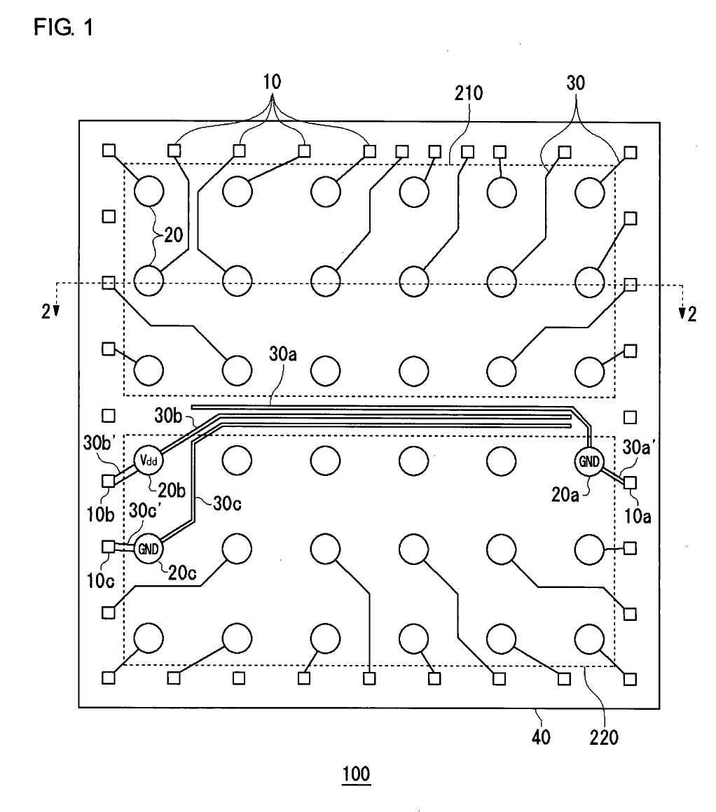

FIG. 1 is a diagram showing a semiconductor device 100 according to an embodiment of the present invention as viewed from the electrode-pad side. The semiconductor device 100 has a CSP structure, and the diagram shows the semiconductor device 100 which includes a plurality of electrode pads 10 provided on a semiconductor substrate 40 for inputting and outputting signals from and to external circuitry, external electrodes 20 formed by solder bumps, and rewiring 30. Note that in the subsequent drawings, the same structural elements will be indicated by the same reference numerals and the description will be omitted as appropriate.

The external electrodes 20 are arranged in a matrix on the surface of the semiconductor device 100. The electrode pads 10 are arranged along the outermost periphery of the semiconductor substrate 40 in such a manner as to enclose the integrated circuit. The external electrodes 20 and the electrode pads 10 are connected with each other via the rewiring 30.

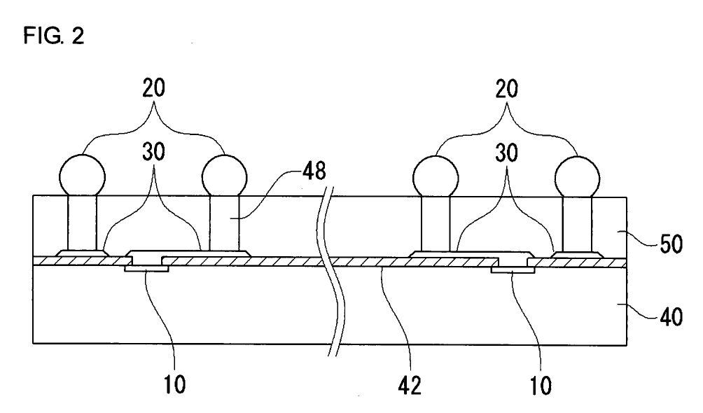

FIG. 2 is a sectional view taken on line 2-2 of FIG. 1. This semiconductor device 100 has a WL-CSP structure which has external connection electrodes formed directly on the semiconductor substrate 40. The semiconductor device 100 includes a semiconductor substrate 40, a protective film 42 for passivation, electrode pads 10, rewiring 30, posts 48, external electrodes 20, and an encapsulating resin 50.

On the top surface of the semiconductor substrate 40, a semiconductor integrated circuit including such circuit elements as transistors and resistances is formed and the electrode pads 10 for input/output of signals are provided. The electrode pads 10 are normally formed of such material as aluminum.

The protective film 42 is a silicon nitride film or the like and has openings formed above the electrode pads 10. The rewiring 30, which is formed of copper, aluminum, gold or the like, leads signals from the electrode pads 10 around to the positions of the external electrodes 20, which are the finally formed positions of the external lead electrodes, and connects them to the posts 48. The columnar posts 48, which are formed of gold, copper, or the like, connect the external electrodes 20 with the rewiring 30 electrically. Note that an insulating layer of an oxide film or a polyimide or other resin film may also be formed over the protective film 42 and the rewiring 30 may be formed on the top thereof.

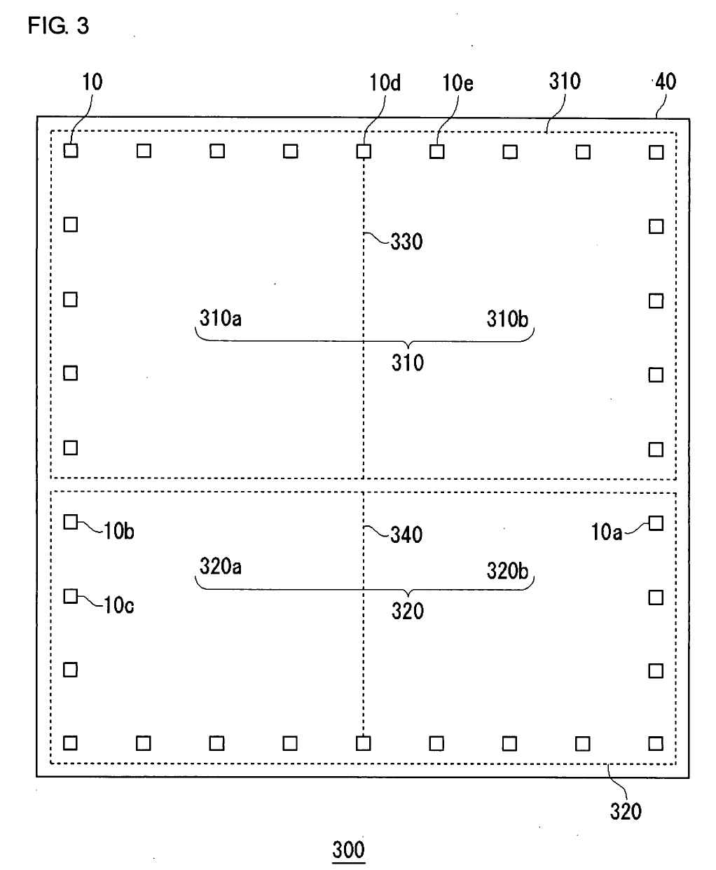

FIG. 3 is a diagram showing an arrangement of a semiconductor integrated circuit 300 formed on the semiconductor substrate 40. As shown in the figure, the semiconductor integrated circuit 300 includes a small-signal circuit 310 and a large-signal circuit 320 as a plurality of function blocks. Since signal interferences that occur between the small-signal circuit 310 and the large-signal circuit 320 can be causes for the malfunction of circuitry and the worsening of the accuracy of signals generated by the semiconductor integrated circuit 300, the small-signal circuit 310 and the large-signal circuit 320 are formed in two separate regions. For example, the small-signal circuit 310 includes a band-gap reference circuit, which is used to generate a reference voltage and constant current, a digital-analog converter, and the like. And the large-signal circuit 320 includes a power transistor to be provided on an output stage for driving a load circuit, among others.

To avoid electrical interference, supply voltage and ground voltage are supplied separately to the small-signal circuit 310 and the large-signal circuit 320, respectively. To achieve that, the small-signal circuit 310 and the large-signal circuit 320 are provided with their respective electrode pads for supplying supply voltage and ground voltage.

In the figure, the electrode pads 10a and 10c are the electrode pads for supplying ground potential to the large-signal circuit 320, whereas the electrode pad 10b is the electrode pad for supplying supply voltage to the large-signal circuit 320. And the electrode pad 10d is the electrode pad for supplying supply voltage to the small-signal circuit 310, whereas the electrode pad 10e is the electrode pad for supplying ground potential to the small-signal circuit 310.

Refer back to FIG. 1. A plurality of external electrodes 20, which are separated into a first group of external electrodes 210 connected to the small-signal circuit 310 and a second group of external electrodes 220 connected to the large-signal circuit 320, are arranged in two separate regions.

In the same way for the external electrodes 20 as for the electrode pads 10, the supply voltage and ground voltage are supplied separately to each function block so as to avoid electrical interference between the small-signal circuit 310 and the large-signal circuit 320.

An external electrode 20a, which is a ground terminal GND, is grounded outside the semiconductor device 100 and connected to an electrode pad 10a via rewiring 30a′, thereby supplying ground voltage to the large-signal circuit 320 of the semiconductor integrated circuit 300.

An external electrode 20b, which is a supply voltage terminal Vdd, is connected to an external voltage source and also connected to an electrode pad 10b via rewiring 30b′, thereby supplying supply voltage to the large-signal circuit 320 of the semiconductor integrated circuit 300.

An external electrode 20c, which is also a ground terminal like the external electrode 20a, is connected to an electrode pad 10c via rewiring 30c′, thereby supplying ground voltage to the large-signal circuit 320.

Further, a semiconductor device 100 according to the present embodiment is provided with rewirings 30a to 30c. These rewirings 30a to 30c are placed in the boundary area between the regions where a first group of external electrodes 210 and a second group of external electrodes 220 are disposed respectively. The rewirings 30a to 30c are connected to external electrodes 20a to 20c, respectively.

Here, external electrodes 20a and 20c are terminals fixed to ground potential, and the external electrodes 20b is a terminal fixed to supply voltage, and they are all of low impedance. Accordingly, the impedance of the rewirings 30a to 30c and rewirings 30a′ to 30c′ connected to these external electrodes 20a to 20c is also set low.

For the rewirings 30a to 30c and rewirings 30a′ to 30c′, which are placed in the boundary area between the first group of external electrodes 210 and the second group of external electrodes 220, it is desirable that the wiring be designed as thick as practicable to reduce the impedance of the rewiring.

As described above, on a semiconductor device 100 according to the present embodiment, a plurality of external electrodes 20 are classified into the first and second groups of external electrodes 210 and 220 according to the function blocks to which they are connected, and the plurality of external electrodes 20 are disposed separately in a plurality of areas according to the plurality of external electrode groups.

Further, placed in the boundary area between the first group of external electrodes 210 and the second group of external electrodes 220 are the rewirings 30a to 30c and 30a′ to 30c′ which are connected to the external electrodes 20 of low impedance.

By rewiring, the first group of external electrodes 210 and the second group of external electrodes 220 are cut off electrically from each other, and the noise signals occurring from the small-signal circuit 310 and the large-signal circuit 320 can be released outside the semiconductor device 100 via the rewirings 30a to 30c and external electrodes 20 of low impedance, thus reducing the signal interferences between the plurality of function blocks.

In the semiconductor device 100 according to the present embodiment, the small-signal circuit 310 and the large-signal circuit 320 are separated from each other by the rewiring 30, so that signal interference can be reduced without increasing the area of the semiconductor substrate 40, and hence the chip cost, compared with the case of separation by the use of multilayer aluminum wiring on the semiconductor integrated circuit 300. Also, since the wiring width of the rewiring 30 can be made as thick as permissible between the external electrodes 20, it is possible to separate the small-signal circuit 310 and the large-signal circuit 320 more effectively.

Further, in a semiconductor device 100 according to the present embodiment, the small-signal circuit 310 and the large-signal circuit 320 are separated electrically from each other by rewirings 30a to 30c and rewirings 30a′ to 30c′, so that the conventional design can be carried out for layers below the protective film 42 in the sectional view shown in FIG. 2, which is before the packaging process.

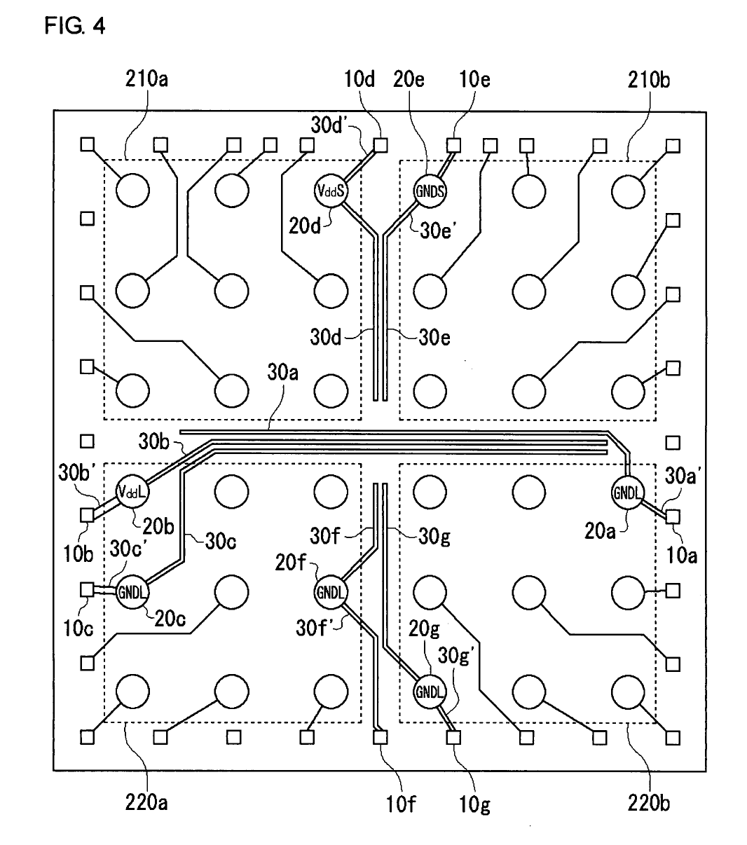

FIG. 4 is a diagram showing a modification of a semiconductor device 100 of FIG. 1. In the semiconductor device 100 of FIG. 4, the small-signal circuit 310 as shown in FIG. 3 is further divided into two circuit blocks 310a and 310b by broken lines 330. Also, the large-signal circuit 320 is divided into two circuit blocks 320a and 320b by broken lines 340.

As a result, as shown in FIG. 4, the external electrodes 20 connected to the respective circuit blocks 310a and 310b are divided into an external electrode group 210a and an external electrode group 210b.

Placed in the small-signal circuit 310 of the semiconductor device 100 of FIG. 4 are rewirings 30d, 30d′, 30e, and 30e′. The rewiring 30d′ is connected to an external electrode 20d for supplying supply voltage to the small-signal circuit 310, whereas the rewiring 30e′ is connected to an external electrode 20e for supplying ground potential to the small-signal circuit 310. The rewiring 30d and the rewiring 30e are placed in the boundary area between the external electrode group 210a and the external electrode group 210b, thereby electrically cutting off the external electrode groups 210a and 210b from each other.

Similarly in the large-signal circuit 320, the external electrode groups 220a and 220b connected respectively to the two circuit blocks 320a and 320b divided by broken lines 340 of FIG. 3 are electrically cut off by rewirings 30f, 30f′, 30g and 30g′.

As shown in FIG. 4, according to the present modification, two or more external electrode groups can also be electrically separated from each other by dividing them by rewiring connected to external electrodes of low impedance, thus reducing the signal interferences between circuit blocks within the small-signal circuit 310 or the large-signal circuit 320.

The technology like this of further dividing the small-signal circuit 310 or the large-signal circuit 320 into a plurality of circuit blocks and electrically separating them by rewiring can be suitably used, for instance, when it is desired that signal interferences be prevented between channels in an integrated circuit which is provided with a plurality of channels of circuits with identical functions.

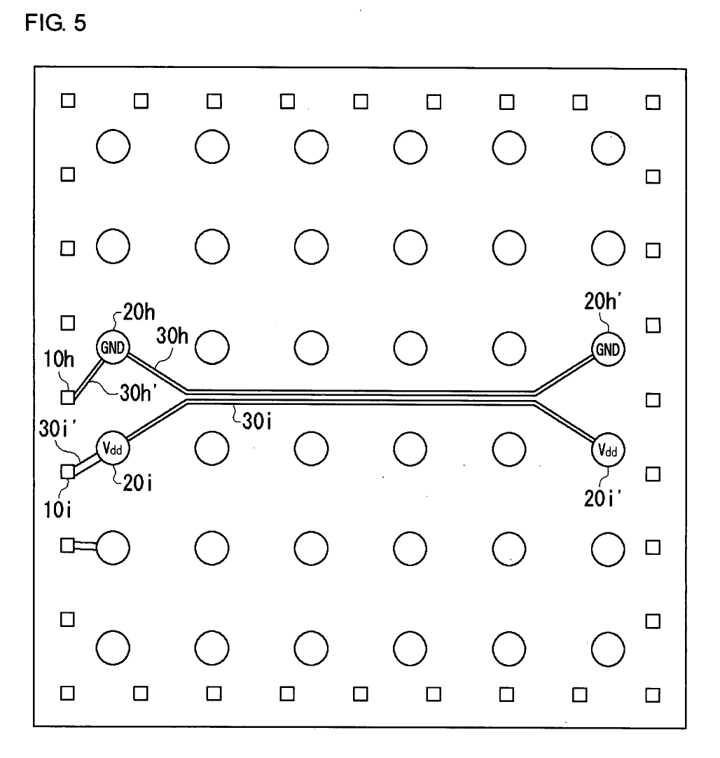

FIG. 5 is a diagram showing another modification of a semiconductor device 100. In FIG. 5, the same structural elements as in FIG. 1 or FIG. 4 are omitted. In this semiconductor device 100, external electrodes 20h and 20h′ are both external lead electrodes for grounding, whereas external electrodes 20i and 20i′ are both electrodes for supplying supply voltage.

In the semiconductor device 100 of FIG. 5, the rewiring 30h is connected to the external electrodes 20h and 20h′ of low impedance at both ends. Similarly, the rewiring 30i is connected to the external electrodes 20i and 20i′ at both ends.

Connected to external electrodes at both ends thereof, the rewirings 30h and 30i are connected to external circuitry via the external electrodes 20h and 20h′ and 20i and 20i′ , respectively. As a result, the connection resistance will be ½ of the case where connection with an external circuit is made via a single external electrode, so that the impedance of rewiring can be further reduced from the level of a semiconductor device 100 as shown in FIG. 1 or FIG. 4. Also, when connection with an external circuit is made via a single external electrode, the resistance component and inductance component of the rewiring increase farther from the external electrode, which results in uneven impedance of the rewiring. Yet, connecting external electrodes at both ends can lower the impedance of the rewiring evenly.

As a result, in the semiconductor device 100 shown in FIG. 5, the noise occurring from the small-signal circuit 310 and the large-signal circuit 320 can be released to external circuitry via the external electrodes 20h, 20h′, 20i, and 20i′, so that signal interference between the small-signal circuit 310 and the large-signal circuit 320 can be reduced more efficiently.

The above embodiments have been described as examples, and it is understood by those skilled in the art that various modifications can be made in the combination of those structural elements and processings and such modifications are within the scope of the present invention.

In the embodiments, descriptions have been given of the case where a semiconductor integrated circuit 300 is divided into two or four function blocks and rewiring is placed in the boundary area of the external electrode groups connected to the respective function blocks. However, the number of thus divided circuit blocks may be set freely according to the characteristics required of the semiconductor device 100.

Also, in the embodiments, descriptions have been given of the case where the small-signal circuit 310 and the large-signal circuit 320 are divided in the middle of the semiconductor device 100 and based on this the first and second external groups of electrodes 210 and 220 are also divided in the middle of the semiconductor 100. However, they are not limited thereto but the division may be made at arbitrary positions according to the size of each circuit.

The region in which the small-signal circuit 310 and the large-signal circuit 320 serving as function blocks are arranged and the region in which the first and second groups of external electrodes 210 and 220 are arranged not always have to be identical. For example, part of the large-signal circuit 320 may overlap with the region in which the first group of external electrodes 210 is arranged.

The number of rewirings to be placed in the boundary area between a plurality of groups of external electrodes may be determined in the light of how much the signal interference among function blocks should be reduced. In the case of a semiconductor device having a CSP structure where the rewiring 30 is multilayered, the rewiring placed in the boundary area between the first group of external electrodes and the second group of external electrodes may be doubly formed. Thereby, the impedance of the rewiring can be further lowered and the signal interference can be further reduced.

In the embodiments, descriptions have been given of the case where the rewiring 30 placed at the boundary area between the first group of external electrodes 210 and the second group of external electrodes 220 are connected to the external electrode 20 for supplying the supply voltage and ground voltage of the large-signal circuit 320. They may be the external electrodes 20 for supplying the supply voltage and ground voltage of the small-signal circuit 310 side or the combination of these.

The present invention can be applied to any of analog circuits, digital circuits and analog-digital mixed circuits, and the production process of semiconductor devices can also be applied to any of bipolar process, CMOS process and BiCMOS process.

1. A semiconductor device, comprising:
a semiconductor substrate on which an integrated circuit including a plurality of function blocks is formed; and
a plurality of external electrodes which are formed as connection terminals to an external circuitry wherein the plurality of external electrodes are connected, via rewiring, to a plurality of electrode pads provided on the integrated circuit,
wherein the plurality of external electrodes are classified into a plurality of groups of external electrodes according to function blocks connected thereto and are arranged in a plurality of divided regions for each of the plurality of groups of external electrodes, and
wherein rewiring connected to an external electrode of low impedance is placed in a boundary area between the plurality of regions.

2. A semiconductor device according to claim 1, wherein at least one function block among the plurality of function blocks is a small-signal circuit for treating small signals.

3. A semiconductor device according to claim 1, wherein the rewiring connected to an external electrode of low impedance is a grounding line connected to an external grounding terminal or a power supply line connected to a supply voltage terminal.

4. A semiconductor device according to claim 2, wherein the rewiring connected to an external electrode of low impedance is a ground line connected to an external ground terminal or a power supply line connected to a supply voltage terminal.

5. A semiconductor device according to claim 1, wherein the rewiring connected to an external electrode of low impedance is provided in plurality, and a plurality of rewirings are placed mutually adjacent.

6. A semiconductor device according to claim 2, wherein the rewiring connected to an external electrode of low impedance is provided in plurality, and a plurality of rewirings are placed mutually adjacent.

7. A semiconductor device according to claim 5, wherein two of the plurality of rewirings connected to external electrodes of low impedance are any of one of combinations among (i) ground line and power supply line, (ii) ground line and ground line and (iii) power supply line and power supply line.

8. A semiconductor device according to claim 5, wherein the rewirings connected to external electrodes of low impedance are such that three lines are placed adjacent in the order of a ground line, a power supply line and a ground line.

9. A semiconductor device according to claim 1, wherein the rewiring connected to an external electrode of low impedance is connected with the external electrodes of low impedance at both ends thereof.

10. A semiconductor device according to claim 2, wherein the rewiring connected to an external electrode of low impedance is connected with the external electrodes of low impedance at both ends thereof.

11. A semiconductor device according to claim 1, wherein the rewiring connected to an external electrode of low impedance is multilayered.

12. A semiconductor device according to claim 2, wherein the rewiring connected to an external electrode of low impedance is multilayered.
